(19) United States
(12) Patent Application Publication
(10) Pub. No.: US 2021/0293583 A1
(43) Pub. Date: Sep. 23, 2021

(54) METHOD FOR CHECKING THE SETTING OF AN ANGULAR POSITION SENSOR OF A ROTOR FOR A VEHICLE

(71) Applicant: Valeo Siemens eAutomotive France SAS, Cergy (FR)

(72) Inventors: Pierre-Alexandre Chauvenet, Cergy (FR); Wided Zine, Paris (FR); Bruno Condamin, Pontoise (FR)

(21) Appl. No.: 17/262,823

(22) PCT Filed: Jul. 24, 2019
(86) PCT No.: PCT/EP2019/069873

§ 371 Date: Jan. 25, 2021

(30) Foreign Application Priority Data
Jul. 27, 2018 (FR) 1857052

(51) Int. Cl. G01D 5/244; H02P 6/18; H02P 21/18; G01D 5/20; G01R 31/00

(52) U.S. Cl. CPC G01D 5/24466; H02P 6/183; G01R 31/006; G01D 5/204; H02P 21/18

(57) ABSTRACT

The present invention concerns a method for checking the setting of an angular position sensor of a rotor of a drive system of a vehicle, said drive system comprising a physical angular position sensor intended to measure the angular position of the rotor relative to a stator of a rotating electric machine of the drive system, such as an electric machine of an electric or hybrid drive system, said method comprising, during an initialisation phase of the drive system, the electric machine not rotating: estimating the angular position of the rotor by means of a method injecting a high-frequency current or voltage signal; measuring the angular position of the rotor, by the physical angular position sensor; calculating the difference between the estimated angular position of the rotor and the measured angular position of the rotor; detecting an anomaly in the setting of the physical angular position sensor if said difference is greater than a predefined threshold.

### CROSS-REFERENCE TO RELATED APPLICATIONS

This application is a National Stage application of International Patent Application No. PCT/EP2019/069873, filed on Jul. 24, 2019, which claims priority to French Patent Application No. 1857052 filed on Jul. 27, 2018, each of which is hereby incorporated by reference in its entirety.

### TECHNICAL FIELD

Generally, the invention relates to controlling an electrical rotating machine, especially with a permanent magnet, of an electrical drive system, such as for example an electric motor system for an electric or hybrid vehicle.

In particular, the present invention is directed to a method for checking timing of the angular position sensor of a rotor—also referred to as driveshaft—of a motor system of a vehicle.

### BACKGROUND

Indeed, in an electrical rotating machine, especially with permanent magnets, the angular position information of the rotor is essential for controlling generation of the requested drive torque.

Generally, an electrical rotating machine comprises a stator corresponding to the fixed part of the machine, and a rotor, corresponding to the rotating part of the machine. Especially in the context of an electric or hybrid motor system for a vehicle, the rotor is integral with the driveshaft. To control generation of the drive torque of the rotor, and therefore the rotational speed of the driveshaft rotatably driven by the electrical rotating machine, it is of the utmost importance to know at any time, with accuracy, the angular position of the driveshaft.

The angular position of the rotor of an electrical rotating machine is thus given by a physical sensor, especially by a resolver or by an “absolute coder” type sensor.

Within this context, the present invention thus relates to checking, in an initializing phase of an electrical rotating machine of a motor system, the proper calibration of the angular position sensor of the rotor of said electrical machine so as to ensure that data coming therefrom, in an operating phase of the vehicle, will be correct.

Such a self-phasing consists in a routine of aligning the resolver with the axis of the rotor of an electrical rotating machine. The purpose thereof is to determine the angular offset between both and to provide this information as an input to a module for controlling said electrical machine.

As previously indicated, commanding the electrical machine requires the absolute angular position of the rotor in order to precisely control the torque requested to the electrical machine. Physical angular position sensors of the rotor, such as the absolute coders and resolvers, have to accurately indicate the angular position of the rotor at any time after the offset between the zero angle of the rotor and that of the sensor has been established during self-phasing.

The present invention does not consist in a self-phasing process but aims at checking that the timing of the physical angular position sensor, consisting of a resolver or absolute coder in particular, is actually correct, in other words that calibration of said physical sensor is correct.

There is no known solution to this problem insofar as it is today considered that angular position sensors of driveshafts, resolvers or absolute coders, are correctly factory-calibrated. A poor calibration of the physical angular position sensor of the rotor of a machine however results in a risk of inappropriate response of torque command, possibly inducing an undesired acceleration or deceleration.

To overcome this drawback, the present invention provides a method for checking timing of a physical angular position sensor of a rotor of an electrical rotating machine.

### SUMMARY

More precisely, the object of the present invention is a method for checking timing of an angular position sensor of a rotor of a motor system for a vehicle, said motor system comprising a physical angular position sensor for measuring the angular position of the rotor relative to a stator of an electrical rotating machine of the motor system, such as an electrical machine of an electric or hybrid motor system, said method comprising, during a phase of initializing the motor system, the electrical machine not rotating:
estimating the angular position of the rotor by a process of injecting a high-frequency current or voltage signal;
measuring the angular position of the rotor by the physical angular position sensor;
calculating the difference between the estimated angular position of the rotor and measured angular position of the rotor;
detecting an anomaly in the timing of the physical angular position sensor if said difference is greater than a predefined threshold.

By virtue of the present invention, an anomaly which occurred upon calibrating the physical sensor for measuring the angular position of the rotor of an electrical rotating machine is detected before starting up said electrical machine, avoiding any risk of generating an inappropriate torque command, and thus increasing safety of the motor system.

According to one embodiment, the method further comprises, if an anomaly in the timing of the physical angular position sensor is detected, inhibiting starting up of the motor.

According to one embodiment, the threshold is equal to 3°.

Especially, the process of injecting a high-frequency current or voltage signal can be a pulsating process.

Alternatively, the process of injecting a high-frequency current or voltage signal can be a rotary process.

The invention is also directed to an electric or hybrid motor system for a vehicle, comprising a driveshaft driven by a rotor of an electrical rotating machine, a physical angular position sensor of the rotor, as well as a module for controlling said electrical machine comprising a module for checking timing of the physical angular position sensor, said module for checking timing of the physical angular position sensor being configured to implement the method briefly described above.

According to one embodiment, the physical angular position sensor is a resolver.

The invention is also directed to an automotive vehicle comprising an electric or hybrid motor system such as briefly described above.

### BRIEF DESCRIPTION OF THE DRAWINGS

The invention will be better understood upon reading the following description, given purely by way of example, and with reference to the appended drawings which represent:

FIG. 1, the schematic diagram of an electric motor system implementing the method according to the invention;

FIG. 2, the block diagram representing the steps of the method according to the invention.

### DETAILED DESCRIPTION

It is reminded that the present invention is described below using different non-limiting embodiments and is likely to be implemented in alternatives within the scope of those skilled in the art, to which the present invention is also directed.

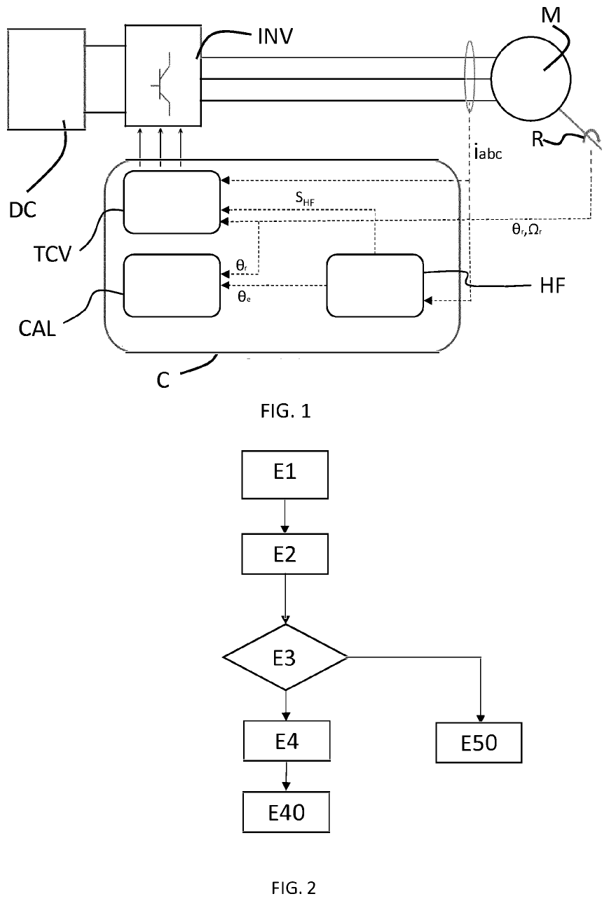

FIG. 1 shows the diagram of an electrical drive system making use of the invention, in particular in order to enable a limp-home application to be implemented in a vehicle.

The electrical drive system depicted in FIG. 1 includes:
a battery DC providing direct current voltage supply;
an inverter INV;
an electrical machine M;
a control module C.

The power stage, comprising the battery DC and inverter INV, supplying the electrical machine M, here is a three-phase stage, but it could also be of a different number of phases.

The control module C comprises a module TCV for commanding the torque requested to the power stage. Input data provided to said module for commanding the torque TCV are angular position θᵣ of the rotor and rotational speed Ωᵣ of the rotor derived therefrom, as well as phase currents i_{abc} of the electrical machine M. These angular position and speed data come from the physical angular position sensor of the rotor, especially a resolver R, and this is the reason why it is of the utmost importance to check that data coming from this physical sensor—resolver R—are correct.

The method according to the invention is implemented before the electrical machine M is actually started up, especially during an initialization phase of such a start-up. Consequently, the torque requested by the commanding module TCV is zero upon implementing the method according to the invention.

Additionally, the angular position of the rotor is also estimated through an estimator HF by a process of injecting a high-frequency current or voltage signal S_{HF}, briefly described hereafter.

The estimator HF thus determines an estimated position θₑ of the rotor.

According to the invention, the control module C further comprises a module CAL for checking timing of the resolver R ensuring checking of the proper calibration of the resolver R, before starting up the electrical machine M.

The module CAL for checking timing of the resolver R receives the angular position θᵣ measured by the resolver R and the angular position θₑ estimated by the estimator HF. The module CAL determines the difference between said measured angular position θᵣ and said estimated angular position θₑ and compares this difference with a predetermined threshold, for example equal to 3°. If said difference is greater than said threshold, then the module CAL for checking timing of the resolver R generates and transmits a fault signal comprising improper timing information for the resolver R.

As is known and already previously discussed, the angular position of the rotor can thus be estimated by numerical processes.

In document US 20110028975 especially, a technique for estimating the angular position of a rotor in an electrical rotating machine is described. The estimation method described in this document implements a well known technique based on injecting high-frequency signals superimposed on the fundamental frequency of the excitation voltage of the electrical machine. In this case, the injected high-frequency voltage is added to the voltage coming from the controller in charge of closed-loop controlling electric currents supplying the electrical machine. At the output of the electrical machine, the current includes a high-frequency component which, after processing, enables the angular position of the rotor to be estimated.

Another process of estimating the angular position of the rotor (and possibly its rotational speed) by injecting a high-frequency current or voltage signal, is described in further detail, and according several embodiments, in document FR 3060908 A1.

In practice, several reference frames are associated with the stator and rotor of the electrical rotating machine respectively.

First, a three-axis fixed reference frame is related to the stator. This three-phase reference frame is often denoted, in the state of the art, as (u, v, w) or as (a, b, c).

The (α, β) reference frame is obtained via a “Clarke” transformation (conservation of amplitude) or a “Concordia” transformation (conservation of power) of the fixed three-phase reference frame, set forth above, related to the stator of the electrical machine.

The (d, q) reference frame corresponds to a common coordinate system enabling stator windings as well as rotor winding of the electrical machine to be represented on a single two-axis reference frame. This reference frame is obtained by applying a rotation by an angle θ, θ being the current angular position of the rotor, to the two-phase reference frame (α,β), or by applying the “Park” transform to the three-phase stator reference frame (u, v, w).

Within this context, an estimator of the angular position of the rotor of the electrical machine is based on injecting a high-frequency current or voltage signal superimposing on the torque command voltages of the electrical machine. Especially, the estimator implements a pulsating process, considered as being simpler and therefore lighter for its implementation on an in-board microcontroller, since the latter is limited in terms of computational capacities. However, the implementation of a rotary process can be provided. Per se, the implementation of a rotary process for injecting a high-frequency current or voltage signal is described in the state of the art, especially in document “Sensorless vector control operation of a PMSM by rotating high-frequency voltage injection approach”, Xiaodong Xiang et al., in “2007 International Conference on Electrical Machines and Systems (ICEMS)”, p. 752-756, published, in 2007, or in document “A New Rotor Position Estimation Method of IPMSM Using All-Pass Filter on High-Frequency Rotating Voltage Signal Injection”, Sang-II Kim et al., in “IEEE Transactions on Industrial Electronics (Volume: 63, Issue: 10, October 2016)”, published on 18 Jul. 2016.

According to the pulsating process, the voltage Vₕ with a frequency fₕ is injected on the estimated axis d of the rotor and superimposed with the reference voltage coming from the command module in order to command the inverter INV in turn supplying the electrical machine M.

In the estimated reference frame (d, q), the expression of the high-frequency component of the current is such that:

$${I}_{dq}^{\hat{r}} = [ {I}_{hp} - {I}_{hn} {e}^{( - 2 j {θ}_{err} )} ] sin ( {ω}_{h} t ) where$$

$$\frac{{I}_{hp}}{2} = \frac{( {L}_{d} + {L}_{q} ) \cdot {V}_{h}}{2 {w}_{h} {L}_{d} {L}_{q}} and \frac{{I}_{hn}}{2} = \frac{( {L}_{d} - {L}_{q} ) \cdot {V}_{h}}{2 {w}_{h} {L}_{d} {L}_{q}} ,$$

L_{d} and L_{q} are the inductances of the electrical machine expressed in the reference frame (d, q). Their values are sensitive to the current level. L_{d} and L_{q} are here considered as mean values over the entire current variation range,
wₕ=2πfₕ
θₑᵣᵣ is the error between the estimated value of the angular position of the rotor and its real position.

After processing, this results in the error θₑᵣᵣ on the angular position estimated by the first estimator HF. From this error, by means of a proportional integral observer, the angular position of the rotor is estimated.

Within this context, the present invention provides a method for checking timing of a physical angular position sensor of a rotor of an electrical rotating machine, especially of a resolver R, before starting up said electrical machine M of a motor system, in other words during an initialization phase of said motor system.

As previously indicated, the method for checking timing of the physical angular position sensor of the rotor of an electric rotating machine M according to the invention is implemented while said rotating machine is switched off, no torque being commanded to the rotor.

With reference to FIG. 2, the method for checking timing of the physical angular position sensor of the rotor comprises a step E1 of estimating the angular position of the rotor by injecting a high-frequency current or voltage signal, as previously described.

Said method additionally comprises a step E2 of determining the difference between the angular position of the rotor measured θᵣ by a physical sensor, especially by a resolver, and the angular position of the rotor estimated ee by an estimator based on injecting a high-frequency current or voltage signal.

In step E3, said difference is compared with a predetermined threshold, for example equal to 3°. If said difference is greater than said threshold, then the method according to the invention comprises generating and transmitting E4 a fault signal comprising improper timing information for the physical angular position sensor. Especially, according to one embodiment, consecutively inhibiting E40 starting up of the electrical machine is provided.

If on the contrary said difference is lower than said threshold, then starting up the electrical machine is allowed E50.

What is claimed is:

1. A method for checking setting of an angular position sensor of a motor system of a vehicle, said motor system comprising a physical angular position sensor for measuring an angular position of the rotor relative to a stator of an electrical rotating machine of the motor system, such as an electrical machine of an electric or hybrid motor system, said method comprising, during an initializing phase of the motor system, the electrical machine not rotating:
estimating the angular position of the rotor by a process for injecting a high-frequency current or voltage signal;
measuring the angular position of the rotor by the physical angular position sensor;
calculating a difference between the estimated angular position of the rotor and measured angular position of the rotor;
detecting an anomaly in the timing of the physical angular position sensor if said difference is greater than a predefined threshold.

2. The method according to claim 1 comprising, if an anomaly in the timing of the physical angular position sensor is detected, inhibiting starting up of the motor.

3. The method according to claim 1, wherein the threshold is equal to 3°.

4. The method according to claim 1, wherein the process of injecting a high-frequency current or voltage signal is a pulsating process.

5. The method according to claim 1, wherein the process for injecting a high-frequency current or voltage signal is a rotary process.

6. An electric or hybrid motor system for a vehicle, comprising a driveshaft driven by a rotor of an electrical rotating machine, a physical angular position sensor of the rotor, as well as a module for controlling said electrical machine comprising a module for checking timing of the physical angular position sensor, said module for checking timing of the physical angular position sensor being configured to implement the method according to claim 1.

7. A system according to claim 6, wherein the physical angular position sensor is a resolver.

8. An automotive vehicle comprising an electric or hybrid motor system according to claim 6.

9. The method according to claim 2, wherein the threshold is equal to 3°.

10. The method according to claim 2, wherein the process of injecting a high-frequency current or voltage signal is a pulsating process.

11. The method according to claim 3, wherein the process of injecting a high-frequency current or voltage signal is a pulsating process.

12. The method according to claim 2, wherein the process for injecting a high-frequency current or voltage signal is a rotary process.

13. The method according to claim 3, wherein the process for injecting a high-frequency current or voltage signal is a rotary process.

14. The method according to claim 4, wherein the process for injecting a high-frequency current or voltage signal is a rotary process.

15. The electric or hybrid motor system for a vehicle according to claim 6, wherein said module for checking timing of the physical angular position sensor being configured to, if an anomaly in the timing of the physical angular position sensor is detected, inhibit starting up of the motor.

16. The electric or hybrid motor system for a vehicle according to claim 6, wherein the threshold is equal to 3°.

17. The electric or hybrid motor system for a vehicle according to claim 6, wherein the process of injecting a high-frequency current or voltage signal is a pulsating process.

18. The electric or hybrid motor system for a vehicle according to claim 6, wherein the process for injecting a high-frequency current or voltage signal is a rotary process.

19. The automotive vehicle according to claim 8, wherein the physical angular position sensor is a resolver.
